(19) United States
(12) Patent Application Publication
(10) Pub. No.: US 2026/0327527 A1
(43) Pub. Date: Oct. 22, 2026

(54) STRIPPER COMPOSITION AND ITS USE AND METHOD FOR STRIPPING PHOTORESIST

(71) Applicant: Advanced Echem Materials Company Limited, Taoyuan (TW)

(72) Inventors: Ting-Ruei Xu, Taoyuan (TW); Yun-Ju Chiang, Taoyuan (TW); Yu-Chen Chiu, Taoyuan (TW); Hsiang-Lin Hsu, Taoyuan (TW)

(73) Assignee: Advanced Echem Materials Company Limited, Taoyuan (TW)

(21) Appl. No.: 19/635,820

(22) Filed: Apr. 1, 2026

(30) Foreign Application Priority Data
Apr. 10, 2025 (TW) 114113449

(51) Int. Cl. C11D 7/50; C11D 7/06; C11D 7/32; G03F 7/42

(52) U.S. Cl. CPC C11D 7/5022; C11D 7/06; C11D 7/3218; G03F 7/425; C11D 2111/22

(57) ABSTRACT

A stripper composition and its use and a method for stripping photoresist are provided. The stripper composition includes an alkoxy diether organic solvent, an alcohol organic solvent, an alkanolamine and an inorganic base. Based on 100 parts by weight of the stripper composition, the alkoxy diether organic solvent is 20 to 55 parts by weight, the alcohol organic solvent is 4 to 39 parts by weight, the alkanolamine is 30 to 48 parts by weight, and the inorganic base is 1.4 to 2.1 parts by weight.

### CROSS-REFERENCE TO RELATED APPLICATION

This application claims the priority benefit of Taiwan application serial no. 114113449, filed on Apr. 10, 2025. The entirety of the above-mentioned patent application is hereby incorporated by reference herein and made a part of this specification.

### BACKGROUND

### Technical Field

The disclosure relates to a stripper composition, and particularly relates to a stripper composition and its use and a method for stripping photoresist.

### Description of Related Art

Currently in semiconductor and related processes, thick film photoresist with thickness reaching 120 micrometers (μm) or greater has been used. Therefore, stripper compositions that may be used to remove thick film photoresist are important research in semiconductor processes.

Common stripper compositions contain aprotic high-polarity solvents, which have excellent dissolving capability for photoresist. However, sulfide-type aprotic high-polarity solvents such as dialkyl sulfoxide (DMSO) and sulfolane may cause environmental pollution, while N-Methyl Pyrrolidone (NMP), N-Ethyl-2-Pyrrolidone (NEP), 1,3-dimethyl-2-imidazolidinone (DMI) and other aprotic high-polarity solvents usually contain reproductive toxins that are harmful to the human body.

Furthermore, common stripper compositions also include alkanolamine, which helps photoresist to peel from the substrate by the stripper composition in high temperature environments. However, during the photoresist stripping process, alkanolamine may corrode the film layer in contact with the photoresist, such as the metal layer or substrate located beneath the photoresist, thereby affecting the performance of semiconductor devices manufactured using it.

Therefore, there is an urgent need for a method that may improve the performance.

### SUMMARY

The disclosure provides a stripper composition with organic solvent free of sulfide and reproductive toxicity, and having environmentally friendly properties, good photoresist stripping capability, and effective inhibition of corrosion at the lower contact surface of the photoresist, suitable for stripping thick film photoresist.

A stripper composition of the disclosure includes an alkoxy diether organic solvent, an alcohol organic solvent, an alkanolamine, and an inorganic base. Based on 100 parts by weight of the stripper composition, the alkoxy diether organic solvent is 20 to 55 parts by weight, the alcohol organic solvent is 4 to 39 parts by weight, the alkanolamine is 30 to 48 parts by weight, and the inorganic base is 1.4 to 2.1 parts by weight.

In an embodiment of the disclosure, the alkoxy diether organic solvent includes a compound shown by the following formula (1), a compound shown by the following formula (2), a compound shown by the following formula (3), or a combination thereof:

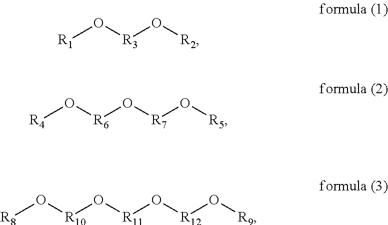

wherein, R₁, R₂, R₄, R₅, R₈, and R₉ are each independently a C₁₋₄ alkyl group; R₃, R₆, R₇, R₁₀, R₁₁, and R₁₂ are each independently a C₁₋₃ alkylene group.

In an embodiment of the disclosure, the alkoxy diether organic solvent includes bis(2-methoxyethoxy)methane, diethylene glycol diethyl ether, diethylene glycol methyl ethyl ether, ethylene glycol dibutyl ether, diethylene glycol dibutyl ether, dipropylene glycol dimethyl ether, or any arbitrary combination thereof.

In an embodiment of the disclosure, the alkoxy diether organic solvent includes a compound having an alkoxy structure with at least two ether groups.

In an embodiment of the disclosure, the alcohol organic solvent includes a compound shown by the following formula (4), a compound shown by the following formula (5), or a combination thereof:

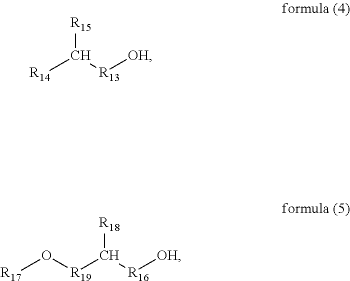

wherein, R₁₃, R₁₆, and R₁₉ are each independently a direct bond or a C₁₋₄ alkylene group; R₁₄ and R₁₇ are each independently a C₁₋₄ alkyl group; R₁₅ and R₁₈ are each independently a C₁₋₂ alkyl group.

In an embodiment of the disclosure, the alcohol organic solvent includes 2-ethylhexanol, propylene glycol n-propyl ether, propylene glycol n-butyl ether, 2-butanol, 2-hexanol, 2-octanol, or any arbitrary combination thereof.

In an embodiment of the disclosure, the alcohol organic solvent includes an alkanol or ether alcohol compound, wherein the alkanol or ether alcohol compound is a monoalcohol and has a branched chain alkyl structure.

In an embodiment of the disclosure, the alkanolamine includes monoethanolamine, isopropanolamine, or a combination thereof.

In an embodiment of the disclosure, the inorganic base includes potassium hydroxide, sodium hydroxide, or a combination thereof.

A use of a stripper composition of the disclosure is for removing a photoresist with a thickness of 100 to 350 μm.

A method for stripping photoresist of the disclosure includes the following steps: providing the stripper composition; and immersing a substrate having a photoresist in the stripper composition.

Based on the above, the stripper composition of the disclosure includes an alkoxy diether organic solvent, an alcohol organic solvent, an alkanolamine, and an inorganic base. Based on 100 parts by weight of the stripper composition, the alkoxy diether organic solvent is 20 to 55 parts by weight, the alcohol organic solvent is 4 to 39 parts by weight, the alkanolamine is 30 to 48 parts by weight, and the inorganic base is 1.4 to 2.1 parts by weight. Compared with conventional stripper compositions, since the stripper composition of the disclosure contains organic solvent free of sulfide and reproductive toxicity, it is more environmentally friendly and safer for human body. In addition, the stripper composition of the disclosure may have both good thick film photoresist stripping capability, and may inhibit corrosion of the lower contact surface during photoresist stripping, thereby enhancing the performance of the subsequently manufactured semiconductor devices.

In order to make the above-mentioned features and advantages of the disclosure clearer and easier to understand, the following embodiments are given and described in detail below.

### DESCRIPTION OF THE EMBODIMENTS

### <Stripper Composition>

The disclosure provides a stripper composition, including an alkoxy diether organic solvent, an alcohol organic solvent, an alkanolamine, and an inorganic base. Additionally, the stripper composition of the disclosure may further include other suitable additives as needed. The following will provide a detailed description of the various components mentioned above.

### Alkoxy Diether Organic Solvent

In the disclosure, the alkoxy diether organic solvent includes a compound having an alkoxy structure with at least two ether groups. Specifically, the alkoxy diether organic solvent of the disclosure includes a compound shown by the following formula (1), a compound shown by the following formula (2), a compound shown by the following formula (3), or a combination thereof.

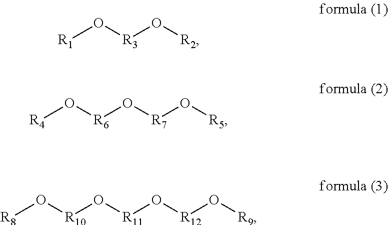

wherein, R₁, R₂, R₄, R₅, R₈, and R₉ are each independently a C₁₋₄ alkyl group; R₃, R₆, R₇, R₁₀, R₁₁, and R₁₂ are each independently a C₁₋₃ alkylene group.

In some embodiments, the alkoxy diether organic solvent may include, for example, bis(2-methoxyethoxy)methane, diethylene glycol diethyl ether, diethylene glycol methyl ethyl ether, ethylene glycol dibutyl ether, diethylene glycol dibutyl ether, dipropylene glycol dimethyl ether, or any arbitrary combination thereof, or other suitable alkoxy diether organic solvents. The alkoxy diether organic solvent may be used alone or in combination with multiple types.

In the disclosure, based on 100 parts by weight of the stripper composition, the content of the alkoxy diether organic solvent is 20 to 55 parts by weight, preferably 25 to 54 parts by weight. In some embodiments, when the content of the alkoxy diether organic solvent is greater than 55 parts by weight or less than 20 parts by weight, the capability to strip the photoresist will be reduced.

When the stripper composition includes an alkoxy diether organic solvent, the alkoxy diether organic solvent may adsorb onto the upper photoresist layer through van der Waals forces at multiple carbon-oxygen bonds, thereby increasing the stripping rate of the upper photoresist layer, allowing the stripper composition to have better stripping capability for the photoresist.

### Alcohol Organic Solvent

In the disclosure, the alcohol organic solvent is a compound composed of monoalcohol with alkyl branch chain alkanol or ether alcohol structure. Specifically, the alcohol organic solvent of the disclosure includes the compound shown by the following formula (4), the compound shown by the following formula (5), or a combination thereof:

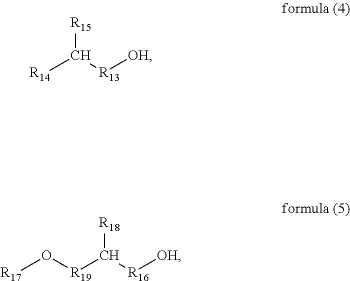

wherein, R₁₃, R₁₆, and R₁₉ are each independently a direct bond or a C₁₋₄ alkylene group; R₁₄ and R₁₇ are each independently a C₁₋₄ alkyl group; R₁₅ and R₁₈ are each independently a C₁₋₂ alkyl group.

In some embodiments, the alcohol organic solvent may be selected from, for example, 2-ethylhexanol, propylene glycol n-propyl ether, propylene glycol n-butyl ether, 2-butanol, 2-hexanol, 2-octanol, or any arbitrary combination thereof, or other suitable alcohol organic solvents. The alcohol organic solvent may be used alone or in combination with multiple types.

In the disclosure, based on 100 parts by weight of the stripper composition, the content of the alcohol organic solvent is 4 to 39 parts by weight, preferably 5 to 34 parts by weight.

When the stripper composition includes an alcohol organic solvent, the alcohol organic solvent may help reduce the capability of the stripper composition to corrode the lower contact surface (for example, the surface of the metal layer and/or substrate), but excessive alcohol organic solvent will lead to a decrease in the capability of the stripper composition to strip the upper photoresist layer.

### Alkanolamine

The alkanolamine of the disclosure is not particularly limited, and an appropriate alkanolamine may be selected according to requirements. In this embodiment, the alkanolamine may include monoethanolamine, triethanolamine, diethanolamine, isopropanolamine, a combination thereof, or other suitable alkanolamines, preferably monoethanolamine, isopropanolamine, or a combination thereof. The alkanolamine may be used alone or in combination with multiple types.

In the disclosure, based on 100 parts by weight of the stripper composition, the content of the alkanolamine is 30 parts by weight to 48 parts by weight, preferably 34 parts by weight to 44 parts by weight.

When the stripper composition includes alkanolamine, the alkanolamine helps improve the solubility of residual photoresist, allowing the stripper composition to have better solubility for the upper photoresist layer, but excessive alcohol organic solvent will lead to an increased corrosion rate of the stripper composition on the underlying substrate.

### Inorganic Base

The inorganic base is not particularly limited and may be selected according to requirements. In this embodiment, the inorganic base may include potassium hydroxide, sodium hydroxide, a combination thereof, or other suitable inorganic bases, preferably potassium hydroxide. The inorganic base may be used alone or in combination with multiple types.

In the disclosure, based on 100 parts by weight of the stripper composition, the content of the inorganic base is 1.4 parts by weight to 2.1 parts by weight, preferably 1.5 parts by weight to 2.0 parts by weight.

When the stripper composition includes an inorganic base, the inorganic base helps break the main chain bonds of large molecules in the photoresist, allowing the stripper composition to effectively enhance the stripping capability of the upper photoresist layer, but excessive inorganic base will lead to an increased corrosion rate of the stripper composition on the underlying substrate.

### <Method for Preparing the Stripper Composition>

The method of preparing the stripper composition is not particularly limited. For example, the alkoxy diether organic solvent, alcohol organic solvent, alkanolamine, and inorganic base were placed in a stirrer and stirred to be uniformly mixed into a solution state. If needed, other suitable additives may also be added. After mixing uniformly, a liquid stripper composition was obtained.

### <Method for Stripping Photoresist>

An exemplary embodiment of the disclosure provides a method for stripping photoresist, including immersing a substrate containing photoresist in the above-mentioned stripper composition.

The substrate may be a glass substrate, silicon wafer substrate, or other suitable substrate material that may resist corrosion by alkaline substances.

The photoresist may be a positive photoresist or a negative photoresist. The photoresist material may include resin, photosensitizer, and solvent. The resin included in the positive photoresist may include phenolic resin or other suitable materials. The resin included in the negative photoresist may include acrylic resin or other suitable materials.

The uppermost layer of one surface of the substrate may have a metal layer formed thereon. The material of the metal layer may include copper or other suitable metals.

Hereinafter, the disclosure is described in detail with reference to examples. The following examples are provided to describe the disclosure, and the scope of the disclosure includes the scope in the following patent application and its substitutes and modifications, and is not limited to the scope of the examples.

### Examples and Comparative Examples of Stripper Compositions

Example 1 to Example 12 and Comparative Example 1 to Comparative Example 13 of the stripper composition are described below:

### Example 1

Referring to Table 1 and Table 2, 39 parts by weight of monoethanolamine (MEA) and 2 parts by weight of potassium hydroxide (KOH) were added to a mixed solvent formed of 30 parts by weight of bis(2-methoxyethoxy)methane (BMEM) and 29 parts by weight of 2-ethylhexanol (2EH), and after stirring uniformly with a stirrer, the stripper composition of Example 1 was prepared.

### Example 2 to Example 12 and Comparative Example 1 to Comparative Example 12

Continuing to refer to Table 1 to Table 2, the stripper compositions of Example 2 to Example 12 and Comparative Example 1 to Comparative Example 13 were prepared using the same steps as Example 1, and the difference lies in: changing the types of components and their content in the stripper composition. The prepared stripper compositions were evaluated using the following evaluation methods, and the results are shown in Table 2 and Table 3.

### Comparative Example 13

Referring to Table 1 and Table 3, 14 parts by weight of diethylene glycol monoethyl ether (DE), 1.5 parts by weight of tetraethylammonium hydroxide (TEAH), 1.5 parts by weight of potassium hydroxide (KOH), 1 part by weight of glycerol, 9 parts by weight of ethylene glycol (MEG), 0.5 parts by weight of polyvinylpyrrolidone (PVP), and 4.6 parts by weight of water were added to a mixed solvent formed of 30 parts by weight of 1,3-dimethyl-2-imidazolidinone (DMI) and 37.9 parts by weight of sulfolane, and after stirring uniformly with a stirrer, the stripper composition of Comparative Example 1 was prepared.

TABLE 1

| Abbreviation | Compound | Structural formula |
|---|---|---|
| BMEM | Bis(2-methoxyethoxy)methane | 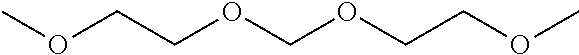 |
| DEGDEE | Diethylene glycol diethyl ether | 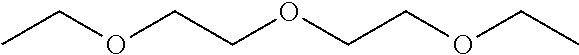 |
| DEGMEE | Diethylene glycol methyl ethyl ether | 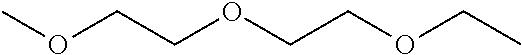 |
| DMM | Dipropylene glycol dimethyl ether | 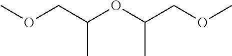 |
| 2EH | 2-Ethylhexanol | 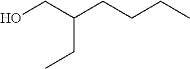 |
| PnB | Propylene glycol n-butyl ether | 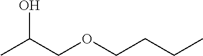 |
| PnP | Propylene glycol n-propyl ether | 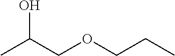 |
| 2-Hexanol | 2-Hexanol | 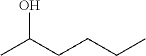 |
| MB | 3-Methoxy-1-butanol | 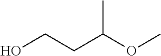 |
| DE | Diethylene glycol monoethyl ether | 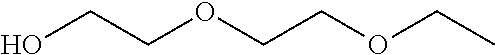 |
| MEG | Ethylene glycol | 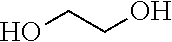 |
| MEA | Monoethanolamine | 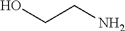 |
| KOH | Potassium hydroxide | K—OH |
| TEAH | Tetraethylammonium hydroxide | 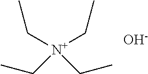 |
| TMAH | Tetramethyl ammonium hydroxide | 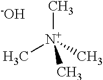 |
| DMI | 1,3-Dimethyl-2-imidazolidinone | 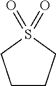 |
| Sulfolane | Sulfolane | 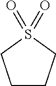 |
| Glycerol | Glycerol | 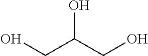 |
| PVP | Polyvinylpyrrolidone | 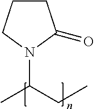 |
| | | n = 360 |

TABLE 2

| | | | Examples | | | | | |
|---|---|---|---|---|---|---|---|---|
| Component (unit: parts by weight) | | | 1 | 2 | 3 | 4 | 5 | 6 |
| Alkoxy diether | | BMEM | 30.0 | 54.0 | 30.0 | 30.0 | 30.0 | 25.0 |
| organic solvent | | DEGDEE | — | — | — | — | — | — |
| | | DEGMEE | — | — | — | — | — | — |
| | | DMM | — | — | — | — | — | — |
| Alcohol | Monoalcohol/ | 2EH | 29.0 | 5.0 | — | — | — | 29.0 |
| organic | branched | PnB | — | — | 5.0 | 5.0 | 5.0 | — |
| solvent | chain | PnP | — | — | 24.0 | — | — | — |
| | | 2-Hexanol | — | — | — | 24.0 | — | — |
| | | MB | — | — | — | — | 24.0 | — |
| | Monoalcohol/ | DE | — | — | — | — | — | — |
| | straight chain | | | | | | | |
| | Diol | MEG | — | — | — | — | — | — |
| Alkanolamine | | MEA | 39.0 | 39.0 | 39.0 | 39.0 | 39.0 | 44.0 |
| Inorganic base | | KOH | 2.0 | 2.0 | 2.0 | 2.0 | 2.0 | 2.0 |
| Organic base | | TEAH | — | — | — | — | — | — |
| | | TMAH | — | — | — | — | — | — |
| Water | | | — | — | — | — | — | — |
| Immersion temperature | | | 70 °C | | | | | |
| Evaluation | | Anti-copper | ⊚ | ⊚ | ⊚ | ⊚ | ⊚ | ⊚ |
| | | corrosion | | | | | | |
| | | capability | | | | | | |
| | | Anti-silicon | ⊚ | ⊚ | ⊚ | ⊚ | ⊚ | ⊚ |
| | | corrosion | | | | | | |
| | | capability | | | | | | |
| | | Anti-PI | ⊚ | ⊚ | ⊚ | ⊚ | ⊚ | ⊚ |
| | | corrosion | | | | | | |
| | | resistance | | | | | | |
| | | 120 μm | ⊚ | ⊚ | ⊚ | ⊚ | ⊚ | ⊚ |
| | | photoresist | | | | | | |
| | | stripping | | | | | | |
| | | capability | | | | | | |
| | | 280 μm | ⊚ | ⊚ | ⊚ | ⊚ | ⊚ | ⊚ |
| | | photoresist | | | | | | |
| | | stripping | | | | | | |
| | | capability | | | | | | |
| | | | Examples | | | | | |
| Component (unit: parts by weight) | | | 7 | 8 | 9 | 10 | 11 | 12 |
| Alkoxy diether | | BMEM | — | — | 20.0 | 30.0 | 30.0 | 40.5 |
| organic solvent | | DEGDEE | 30.0 | — | — | — | — | — |
| | | DEGMEE | — | 30.0 | — | — | — | — |
| | | DMM | — | — | 10.0 | — | — | — |
| Alcohol | Monoalcohol/ | 2EH | — | 24.0 | — | 34.0 | 29.0 | 14.0 |
| organic | branched | PnB | 5.0 | 5.0 | 29.0 | — | — | — |
| solvent | chain | PnP | — | — | — | — | — | — |
| | | 2-Hexanol | 24.0 | — | — | — | — | — |
| | | MB | — | — | — | — | — | — |
| | Monoalcohol/ | DE | — | — | — | — | — | — |
| | straight chain | | | | | | | |
| | Diol | MEG | — | — | — | — | — | — |
| Alkanolamine | | MEA | 39.0 | 39.0 | 39.0 | 34.0 | 39.5 | 44.0 |
| Inorganic base | | KOH | 2.0 | 2.0 | 2.0 | 2.0 | 1.5 | 1.5 |
| Organic base | | TEAH | — | — | — | — | — | — |
| | | TMAH | — | — | — | — | — | — |
| Water | | | — | — | — | — | — | — |
| Immersion temperature | | | 70 °C | | | | | |
| Evaluation | | Anti-copper | ⊚ | ⊚ | ⊚ | ⊚ | ⊚ | ⊚ |
| | | corrosion | | | | | | |
| | | capability | | | | | | |
| | | Anti-silicon | ⊚ | ⊚ | ⊚ | ⊚ | ⊚ | ⊚ |
| | | corrosion | | | | | | |
| | | capability | | | | | | |
| | | Anti-PI | ⊚ | ⊚ | ⊚ | ⊚ | ⊚ | ⊚ |
| | | corrosion | | | | | | |
| | | resistance | | | | | | |
| | | 120 μm | ⊚ | ⊚ | ⊚ | ⊚ | ⊚ | ⊚ |
| | | photoresist | | | | | | |
| | | stripping | | | | | | |
| | | capability | | | | | | |
| | | 280 μm | ⊚ | ⊚ | ⊚ | ⊚ | ⊚ | ⊚ |
| | | photoresist | | | | | | |
| | | stripping | | | | | | |
| | | capability | | | | | | |
| | | | Comparative Examples | | | | | |
| Component (unit: parts by weight) | | | 1 | 2 | 3 | 4 | 5 | 6 |
| Alkoxy diether | | BMEM | 40.0 | 30.0 | — | 20.0 | 45.0 | 45.0 |
| organic solvent | | DEGDEE | — | — | — | — | — | — |
| | | DEGMEE | — | — | — | — | — | — |
| | | DMM | — | — | — | — | — | — |
| Alcohol | Monoalcohol/ | 2EH | 38.0 | 39.0 | — | 29.0 | 47.0 | — |
| organic | branched | PnB | — | — | — | — | — | — |
| solvent | chain | PnP | — | — | — | — | — | — |
| | | 2-Hexanol | — | — | — | — | — | — |
| | | MB | — | — | — | — | — | — |
| | Monoalcohol/ | DE | — | — | 44.0 | — | — | 42.0 |
| | straight chain | | | | | | | |
| | Diol | MEG | — | — | — | — | — | 5.0 |
| Alkanolamine | | MEA | 20.0 | 29.0 | 54.0 | 49.0 | 5.0 | 5.0 |
| Inorganic base | | KOH | 2.0 | 2.0 | 2.0 | 2.0 | 3.0 | 3.0 |
| Organic base | | TEAH | — | — | — | — | — | — |
| | | TMAH | — | — | — | — | — | — |
| Water | | | — | — | — | — | — | — |
| Immersion temperature | | | 70 °C | | | | | |
| Evaluation | | Anti-copper | ⊚ | ⊚ | ⊚ | ◯ | ⊚ | ⊚ |
| | | corrosion | | | | | | |
| | | capability | | | | | | |
| | | Anti-silicon | Δ | ⊚ | ⊚ | ⊚ | X | X |
| | | corrosion | | | | | | |
| | | capability | | | | | | |
| | | Anti-PI | ⊚ | ⊚ | Δ | ◯ | ⊚ | ⊚ |
| | | corrosion | | | | | | |
| | | resistance | | | | | | |
| | | 120 μm | X | ⊚ | ⊚ | ⊚ | X | ⊚ |
| | | photoresist | | | | | | |
| | | stripping | | | | | | |
| | | capability | | | | | | |
| | | 280 μm | X | ◯ | ◯ | ⊚ | X | ⊚ |
| | | photoresist | | | | | | |
| | | stripping | | | | | | |
| | | capability | | | | | | |
| | | | Comparative Examples | | | | | |
| Component (unit: parts by weight) | | | 7 | 8 | 9 | 10 | 11 | 12 |
| Alkoxy diether | | BMEM | 29.5 | 30.0 | 30.0 | 30.0 | 30.0 | 30.0 |
| organic solvent | | DEGDEE | — | — | — | — | — | — |
| | | DEGMEE | — | — | — | — | — | — |
| | | DMM | — | — | — | — | — | — |
| Alcohol | Monoalcohol/ | 2EH | 29.0 | 29.0 | 5.0 | 23.0 | — | — |
| organic | branched | PnB | — | — | — | — | — | — |
| solvent | chain | PnP | — | — | — | — | — | — |
| | | 2-Hexanol | — | — | — | — | — | — |
| | | MB | — | — | — | — | — | — |
| | Monoalcohol/ | DE | — | — | 58.9 | — | — | 29.0 |
| | straight chain | | | | | | | |
| | Diol | MEG | — | — | — | — | 29.0 | — |
| Alkanolamine | | MEA | 39.0 | 37.1 | — | 39.0 | 39.0 | 39.0 |
| Inorganic base | | KOH | 2.5 | 1.0 | 1.8 | — | 2.0 | 2.0 |
| Organic base | | TEAH | — | 1.0 | 1.5 | — | — | — |
| | | TMAH | — | — | — | 2.0 | — | — |
| Water | | | — | 1.9 | 2.8 | 6.0 | — | — |
| Immersion temperature | | | 70 °C | | | | | |
| Evaluation | | Anti-copper | ⊚ | Δ | ◯ | Δ | ⊚ | ◯ |
| | | corrosion | | | | | | |
| | | capability | | | | | | |
| | | Anti-silicon | X | X | X | X | ◯ | ⊚ |
| | | corrosion | | | | | | |
| | | capability | | | | | | |
| | | Anti-PI | ⊚ | Δ | ◯ | Δ | Δ | ◯ |
| | | corrosion | | | | | | |
| | | resistance | | | | | | |
| | | 120 μm | ⊚ | ⊚ | ⊚ | Δ | Δ | ⊚ |
| | | photoresist | | | | | | |
| | | stripping | | | | | | |
| | | capability | | | | | | |
| | | 280 μm | ⊚ | ◯ | ⊚ | X | X | ⊚ |
| | | photoresist | | | | | | |
| | | stripping | | | | | | |
| | | capability | | | | | | |

TABLE 3

| | | | Example | Comparative |
|---|---|---|---|---|
| Component (unit: parts by weight) | | | 1 | Example 13 |
| Other | Reproductive toxicity | DMI | — | 30.0 |
| organic | category 2 | | | |
| solvents | Sulfide | Sulfolane | — | 37.9 |
| Alkoxy diether organic solvent | | BMEM | 30.0 | — |
| Alcohol | Monoalcohol/branched | 2EH | 29.0 | — |
| organic | chain | | | |
| solvent | Monoalcohol/straight | DE | — | 14.0 |
| | chain | | | |
| Alkanolamine | | MEA | 39.0 | — |
| Inorganic base | | KOH | 2.0 | 1.5 |
| Organic base | | TEAH | — | 1.5 |
| Substrate corrosion inhibitor | | Glycerol | — | 1.0 |
| | | MEG | — | 9.0 |

| | | |
|---|---|---|
| PVP | — | 0.5 |

| Water | | — | | | 4.6 | | |
|---|---|---|---|---|---|---|---|
| Immersion temperature | | 70 °C | 65 °C | 60 °C | 70 °C | 65 °C | 60 °C |
| Evaluation | Anti-copper corrosion capability | ⊚ | ⊚ | ⊚ | ⊚ | ⊚ | ⊚ |
| | Anti-silicon corrosion capability | ⊚ | ⊚ | ⊚ | ⊚ | ⊚ | ⊚ |
| | Anti-PI corrosion resistance | ⊚ | ⊚ | ⊚ | ⊚ | ⊚ | ⊚ |
| | 120 μm photoresist stripping | ⊚ | ⊚ | ⊚ | ⊚ | ◯ | Δ |
| | capability | | | | | | |
| | 280 μm photoresist stripping | ⊚ | ⊚ | ◯ | ⊚ | Δ | X |
| | capability | | | | | | |

### Evaluation Method

a. Resistance Against Copper Corrosion

The substrate with a copper layer plated on the surface was immersed in the stripper compositions prepared by the Examples and Comparative Examples, and immersed at a temperature of 60 to 70° C. for 70 minutes. Then, the immersed copper layer substrate was cleaned with deionized water and isopropanol. Then, the etching rate of the copper layer conductor on the substrate was detected using the four-point probe principle. The measurement method of the four-point probe (model LRS4-TG1, manufactured by KeithLink Technology Co., Ltd.) is to apply a fixed current between two of the probes while measuring the voltage difference between the other two probes, thereby calculating the sheet resistance. Then, the change in thickness of the copper layer was calculated through a known formula to calculate the copper corrosion rate, and this was used to evaluate the resistance against copper corrosion. When the copper corrosion rate is slower, it indicates that the stripper composition has good capability to inhibit corrosion of the copper layer surface during photoresist stripping.

The evaluation criteria for resistance against copper corrosion are as follows:
⊚: copper corrosion rate<0.2 Å/minute (Å/min);
◯: 0.2 Å/minute≤copper corrosion rate<2 Å/minute;
Δ: 2 Å/minute≤copper corrosion rate<10 Å/minute;
X: 10 Å/minute≤copper corrosion rate.
   b. Resistance Against Silicon Corrosion

The silicon substrate was immersed in the stripper compositions prepared by the Examples and Comparative Examples, and immersed at a temperature of 60 to 70° C. for 70 minutes. Then, the immersed silicon substrate was cleaned with deionized water and isopropanol, and the silicon substrate was observed with the naked eye to see if it had been corroded, so as to evaluate the resistance against silicon corrosion. When the degree of corrosion/hazing on the silicon substrate surface is smaller, it indicates that the stripper composition has good capability to inhibit corrosion of the silicon substrate during photoresist stripping.

The evaluation criteria for resistance against silicon corrosion are as follows:
⊚: silicon substrate was not corroded; 0: silicon substrate surface was partially hazed;
Δ: silicon substrate surface was completely hazed;
X: silicon substrate was completely exposed.
   c. Resistance Against PI Corrosion

The substrate coated with a polyimide (PI) layer was immersed in the stripper compositions prepared by the Examples and Comparative Examples, and immersed at a temperature of 60 to 70° C. for 70 minutes. Then, the immersed substrate coated with the polyimide layer was cleaned with deionized water and isopropanol. Then, the thickness of the polyimide layer on the cleaned substrate coated with the polyimide layer was measured using a film thickness meter (model Dektak 8, manufactured by Veeco Instruments Inc.) to calculate the corrosion rate of the polyimide layer, and to evaluate the resistance against PI corrosion. When the PI corrosion rate is slower, it indicates that the stripper composition has good capability to inhibit corrosion of the polyimide layer during photoresist stripping.

The evaluation criteria for resistance against PI corrosion are as follows:
⊚: PI corrosion rate<0.03 μm/minute (μm/min);
◯: 0.03 μm/minute≤PI corrosion rate<0.06 μm/minute;
Δ: 0.06 μm/minute≤PI corrosion rate<0.14 μm/minute;
X: 0.14 μm/minute≤PI corrosion rate.
   d. Photoresist Stripping Capability

The substrate containing photoresist (with thickness of 120 m and/or 280 m, for example, negative photoresist) was immersed in the stripper compositions prepared by the Examples and Comparative Examples, and immersed at a temperature of 60 to 70° C. for 70 minutes. Then, the immersed substrate was cleaned with deionized water and isopropanol. Then, the cleaned substrate was observed using a metallurgical microscope (model Nikon LV150N, manufactured by Nikon Corporation) to check whether there was photoresist residue on the substrate, so as to evaluate the stripping capability. When the proportion of photoresist stripped from the substrate is higher, it indicates that the stripper composition has good stripping capability.

The evaluation criteria for photoresist stripping capability are as follows: ⊚: Photoresist completely stripped from the substrate; ◯: 97%<proportion of photoresist stripped from the substrate<100%; Δ: 90%<proportion of photoresist stripped from the substrate≤97%; X: proportion of photoresist stripped from the substrate≤90%.

### Evaluation Results

As shown in Table 2, when the stripper composition includes the alkoxy diether organic solvent, alcohol organic solvent, alkanolamine, and inorganic base, and based on 100 parts by weight of the stripper composition, the alkoxy diether organic solvent is 20 to 55 parts by weight, the alcohol organic solvent is 4 to 39 parts by weight, the alkanolamine is 30 to 48 parts by weight, and the inorganic base is 1.4 to 2.1 parts by weight (Examples 1 to 12), the stripper composition simultaneously has good photoresist stripping capability (120/280 m photoresist completely stripped from the substrate) and the capability to inhibit corrosion of the lower contact surface during photoresist stripping (in the case where the lower contact surface is copper, silicon, or PI, the copper corrosion rate<0.2 Å/minute, silicon substrate is not corroded, and PI corrosion rate<0.03 μm/minute), and may be applicable for stripping thick film photoresist.

Referring to Table 2 again, the differences between Example 1 and Comparative Example 11 and Comparative Example 12 are in the use of different types of alcohol organic solvents to prepare the stripper composition. Specifically, Example 1 uses 2-ethylhexanol, which is a monoalcohol compound with branched chain structure; Comparative Example 11 uses ethylene glycol, which is a diol compound; and Comparative Example 12 uses diethylene glycol monoethyl ether, which is a monoalcohol compound with straight chain structure. The evaluation results show that the 120/280 m photoresist stripping capability and the capability to inhibit corrosion of the lower contact surface as silicon or PI during photoresist stripping of Example 1 are both superior to Comparative Example 11, and the capability to inhibit corrosion of the lower contact surface as copper or PI during photoresist stripping of Example 1 is superior to Comparative Example 12. The above results show that, compared to stripper compositions using monoalcohol compound with straight chain structure or diol compound as alcohol organic solvents, stripper compositions using monoalcohol compound with branched chain structure as alcohol organic solvents may simultaneously have excellent thick film photoresist stripping capability and the capability to inhibit corrosion of the lower contact surface during photoresist stripping.

Continuing to refer to Table 2, the main differences between Examples 1 to 12 and Comparative Example 8 and Comparative Example 10 are that the stripper compositions in Comparative Example 8 and Comparative Example 10 include organic base. Specifically, the stripper compositions of Examples 1 to 12 contain inorganic base and do not contain organic base; the stripper composition of Comparative Example 8 contains inorganic base and organic base; and the stripper composition of Comparative Example 10 contains organic base and does not contain inorganic base. The evaluation results show that the 280 m photoresist stripping capability and the capability to inhibit corrosion of the lower contact surface as copper, silicon, or PI during photoresist stripping of Examples 1 to 12 are all superior to Comparative Example 8, and the 120/280 μm photoresist stripping capability and the capability to inhibit corrosion of the lower contact surface as copper, silicon, or PI during photoresist stripping of Examples 1 to 12 are all far superior to Comparative Example 10. From the above results, it can be inferred that the stripper composition preferably contains inorganic base and does not contain organic base, thereby having excellent thick film photoresist stripping capability, and excellent capability to inhibit corrosion of the lower contact surface during photoresist stripping.

Table 3 shows a comparison of the photoresist stripping capability and the capability to inhibit corrosion of the lower contact surface during photoresist stripping between the stripper composition of the disclosure (Example 1) and a conventional stripper composition (Comparative Example 13) at different immersion temperatures. The results show that the stripper composition with organic solvent free of sulfide and reproductive toxicity (Example 1) may effectively strip/remove thick film photoresist with thickness greater than 120 m at a lower immersion temperature (below 70° C.), while also having the capability to inhibit corrosion of the lower contact surface as copper, silicon, or PI.

According to the stripper composition of the disclosure, the thick film photoresist that may be removed includes negative and positive photoresist, which may be cleaned at a temperature of 40 to 90° C., preferably cleaned at a temperature of 60 to 85° C., and removes thick film photoresist with a thickness of 100 to 350 μm, preferably thick film photoresist with a thickness of 150 to 300 μm. The method for stripping photoresist involved immersing the substrate containing thick film photoresist in the stripper composition for 40 to 120 minutes at an appropriate temperature (such as 60 to 85° C.), preferably for 50 to 90 minutes, and then washing sequentially with water and isopropanol, and blowing dry with high purity nitrogen gas. The test results show that thick film photoresist layers with thickness less than 350 μm can be removed. The stripper composition of the disclosure may control the corrosion rate of the copper layer at the lower contact surface to be less than 0.2 Å/minute, and the corrosion rate of the PI substrate at the lower contact surface to be less than 0.03 μm/minute, and the surface of the Si substrate at the lower contact surface may remain intact.

In summary, the stripper composition of the disclosure includes an alkoxy diether organic solvent, an alcohol organic solvent, an alkanolamine, and an inorganic base. Based on 100 parts by weight of the stripper composition, the alkoxy diether organic solvent is 20 to 55 parts by weight, the alcohol organic solvent is 4 to 39 parts by weight, the alkanolamine is 30 to 48 parts by weight, and the inorganic base is 1.4 to 2.1 parts by weight. Compared with conventional stripper compositions, since the stripper composition of the disclosure contains organic solvent free of sulfide and reproductive toxicity, it is more environmentally friendly and safer for human body. In addition, the stripper composition of the disclosure may have both good thick film photoresist stripping capability, and may inhibit corrosion of the lower contact surface during photoresist stripping, thereby enhancing the performance of the subsequently manufactured semiconductor devices.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A stripper composition, comprising:
an alkoxy diether organic solvent;
an alcohol organic solvent;
an alkanolamine; and
an inorganic base,
wherein based on 100 parts by weight of the stripper composition, the alkoxy diether organic solvent is 20 to 55 parts by weight, the alcohol organic solvent is 4 to 39 parts by weight, the alkanolamine is 30 to 48 parts by weight, and the inorganic base is 1.4 to 2.1 parts by weight.

2. The stripper composition according to claim 1, wherein the alkoxy diether organic solvent comprises a compound shown by the following formula (1), a compound shown by the following formula (2), a compound shown by the following formula (3), or a combination thereof: 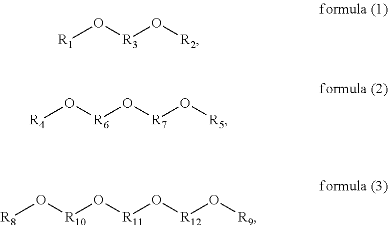
wherein, R₁, R₂, R₄, R₅, R₈, and R₉ are each independently a C₁₋₄ alkyl group; R₃, R₆, R₇, R₁₀, R₁₁, and R₁₂ are each independently a C₁₋₃ alkylene group.

3. The stripper composition according to claim 1, wherein the alkoxy diether organic solvent comprises bis(2-methoxyethoxy)methane, diethylene glycol diethyl ether, diethylene glycol methyl ethyl ether, ethylene glycol dibutyl ether, diethylene glycol dibutyl ether, dipropylene glycol dimethyl ether, or any arbitrary combination thereof.

4. The stripper composition according to claim 1, wherein the alkoxy diether organic solvent comprises a compound having an alkoxy structure with at least two ether groups.

5. The stripper composition according to claim 1, wherein the alcohol organic solvent comprises a compound shown by the following formula (4), a compound shown by the following formula (5), or a combination thereof: 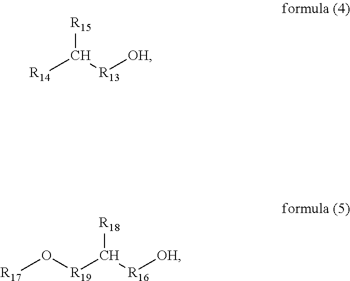
wherein, R₁₃, R₁₆, and R₁₉ are each independently a direct bond or a C₁₋₄ alkylene group; R₁₄ and R₁₇ are each independently a C₁₋₄ alkyl group; R₁₅ and R₁₈ are each independently a C₁₋₂ alkyl group.

6. The stripper composition according to claim 1, wherein the alcohol organic solvent comprises 2-ethylhexanol, propylene glycol n-propyl ether, propylene glycol n-butyl ether, 2-butanol, 2-hexanol, 2-octanol, or any arbitrary combination thereof.

7. The stripper composition according to claim 1, wherein the alcohol organic solvent comprises an alkanol or ether alcohol compound, and the alkanol or ether alcohol compound is a monoalcohol and has a branched chain alkyl structure.

8. The stripper composition according to claim 1, wherein the alkanolamine comprises monoethanolamine, isopropanolamine, or a combination thereof.

9. The stripper composition according to claim 1, wherein the inorganic base comprises potassium hydroxide, sodium hydroxide, or a combination thereof.

10. A use of the stripper composition according to claim 1 for removing a photoresist with a thickness of 100 to 350 μm.

11. A method for stripping photoresist, comprising:
providing the stripper composition according to claim 1; and
immersing a substrate having a photoresist in the stripper composition.
